(19) United States
(12) Patent Application Publication
(10) Pub. No.: US 2026/0076258 A1
(43) Pub. Date: Mar. 12, 2026

(54) PACKAGE STRUCTURES AND METHODS OF FORMING SAME

(71) Applicant: Taiwan Semiconductor Manufacturing Company, Ltd., Hsin-Chu (TW)

(72) Inventors: Jyun-Siang Peng, Hsinchu City (TW); Meng-Wei Chou, Zhubei City (TW); Yu-Hsiang Hu, Hsinchu City (TW); Chien-Hsun Lee, Chu-Tung Town (TW); Kathy Wei Yan, Hsinchu (TW)

(21) Appl. No.: 18/989,614

(22) Filed: Dec. 20, 2024

Related U.S. Application Data
(60) Provisional application No. 63/693,891, filed on Sep. 12, 2024.

(51) Int. Cl. H01L 25/16; H01L 21/02; H01L 21/304; H01L 21/48; H01L 21/56; H01L 23/00; H01L 23/31; H01L 23/367; H01L 23/528; H01L 23/538; H10B 80/00; H10D 80/30

(52) U.S. Cl. CPC H10W 90/00; H10B 80/00; H10D 80/30; H10P 52/00; H10P 70/23; H10W 20/435; H10W 40/037; H10W 70/611; H10W 74/016; H10W 90/401; H10W 40/226; H10W 72/01255; H10W 72/01257; H10W 72/222; H10W 72/227; H10W 72/252; H10W 74/117; H10W 74/15; H10W 90/726; H10W 90/734

(57) ABSTRACT

A method includes providing an interposer structure including conductive paths, forming micro bumps over the interposer structure and connected to the conductive paths, bonding a first die and a second die onto the micro bumps, forming a molding compound over and around the first die and the second die, performing a planarization process to expose a top surface of the second die, forming a trench in the molding compound to expose a top surface of the first die, forming a thermal interface material (TIM) layer in the trench and over the top surface of the second die, bonding the interposer structure to a substrate, and attaching a heat sink onto the TIM layer. The first die has a first height and the second die has a second height greater than the first height.

### PRIORITY DATA

This application claims the benefit of U.S. Provisional Application No. 63/693,891 filed Sep. 12, 2024, the entirety of which is herein incorporated.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

In advanced IC device packages, IC devices can be vertically stacked and compactly packaged to maximize functional density. The 2.5- or 3-dimensional packaging presents a challenge on effectively dissipating the heat generated in the device packages. While existing package structures are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a package structure, according to one or more aspects of the present disclosure.

FIGS. 2, 3A, 3B, 5, 6, 7, 10, 11A, 11B, 12A, and 12B illustrate fragmentary cross-sectional views of an exemplary package structure during various fabrication stages in the method of FIG. 1, according to one or more aspects of the present disclosure.

FIG. 3C illustrates a fragmentary schematic top view of the exemplary package structure during various fabrication stages in the method of FIG. 1, according to one or more aspects of the present disclosure.

FIGS. 4A, 4B, and 4C illustrate alternative fragmentary schematic top views of the exemplary package structure during various fabrication stages in the method of FIG. 1, according to one or more aspects of the present disclosure.

FIG. 8 illustrates an alternative fragmentary perspective view of the exemplary package structure during various fabrication stages in the method of FIG. 1, according to one or more aspects of the present disclosure.

FIG. 9 illustrates a fragmentary schematic cross-sectional view of the exemplary package structure taken along line B-B′ of FIG. 8, according to one or more aspects of the present disclosure.

FIGS. 13, 16A, and 16B illustrate fragmentary cross-sectional views of an alternative package structure during various fabrication stages in the method of FIG. 1, according to one or more aspects of the present disclosure.

FIG. 14 illustrates an alternative fragmentary perspective view of the alternative package structure during various fabrication stages in the method of FIG. 1, according to one or more aspects of the present disclosure.

FIG. 15 illustrates a fragmentary schematic cross-sectional view of the exemplary package structure taken along line B-B′ of FIG. 14, according to one or more aspects of the present disclosure.

FIGS. 17A and 17B illustrate fragmentary cross-sectional views of an alternative package structure during various fabrication stages in the method of FIG. 1, according to one or more aspects of the present disclosure.

FIG. 18 illustrates a flowchart of a method for forming a package structure, according to one or more aspects of the present disclosure.

FIGS. 19, 20, 21, 22, 23, 24, 25A, and 25B illustrate fragmentary cross-sectional views of an exemplary package structure during various fabrication stages in the method of FIG. 18, according to one or more aspects of the present disclosure.

FIGS. 26A, 26B, and 27 illustrate fragmentary cross-sectional views of alternative package structures during various fabrication stages in the method of FIG. 18, according to one or more aspects of the present disclosure.

FIGS. 28A and 28B illustrate fragmentary cross-sectional views of alternative package structures during various fabrication stages in the method of FIGS. 1 and 18, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As the demand for shrinking electronic devices has grown, a need for smaller and more creative packaging techniques of semiconductor dies has emerged. An example of such packaging systems is a Chip-On-Wafer-On-Substrate (CoWoS) structure, where a semiconductor chip (or a device die) is attached to a wafer (e.g., an interposer) to form a Chip-On-Wafer (CoW) structure. The CoW structure is then attached to a substrate (e.g., a printed circuit board) to form a CoWoS structure. These and other advanced packaging technologies enable production of semiconductor devices with enhanced functionalities and small footprints. The heat generated by the device dies during operation needs to be properly dissipated to prevent performance degradation or even physical damage. To meet the power demands of more power and more condensed chip space (e.g., in high performance computing (HPC) and artificial intelligence (AI) applications), heat dissipation in existing semiconductor packages require improvements.

The present disclosure provides integrated circuit (IC) package structures and methods of forming same. More specifically, the present disclosure provides IC package structures including a package substrate, an interposer bonded to the package substrate, a first die disposed over and connected to the interposer by first micro bumps, a second die disposed over and connected to the interposer by second micro bumps, a thermal interface material (TIM) and optionally a backside metallization (BSM) structure disposed on the top surfaces of the first die and the second die, and a heat sink disposed on the TIM. The first die has a first height, and the second die has a second height greater than the first height. In some examples, the first micro bumps and the second micro bumps are formed simultaneously and have similar heights, and the top surface of the first die is lower than the top surface of the second die. In such examples, a local thinning process is performed in the fabrication of the IC package structure. In some other examples, the first micro bumps have a third height, the second micro bumps have a fourth height less than the third height, and the top surface of the first die and the top surface of the second die are at a same level. In such examples, the first micro bumps and the second micro bumps of different heights are formed separately. While the first die and the second die having different heights, by performing the local thinning process and/or by forming micro bumps of different heights, the TIM and optionally the BSM layer can be formed on the top surfaces of the first die and the second die, thus heat dissipation from the first die and the second die may be improved.

The IC package structure disclosed herein may include 2.5D and/or 3D IC heterogenous integrated structures. In a 2.5D structure, at least two dies are coupled to a redistribution layer (RDL) structure (e.g., an interposer) that provides chip-to-chip communication. The at least two dies in a 2.5D structure are not stacked one over another vertically. In a 3D structure, at least two dies are stacked one over another and interact with each other by way of through silicon vias (TSVs). The 2.5D and 3D structures may combine high bandwidth memory (HBM) and system-on-chip (SoC) dies into a single semiconductor package. An SoC die combines elements of a computing or electronic system such as CPU, memory, etc., that were originally in separate chips. Some of the SoC dies may be System-on-Integrated-Chips (SoIC) dies, which are composite dies having vertically stacked dies. In this way, 2.5D structures that have SoIC dies may also be viewed as 3D structures.

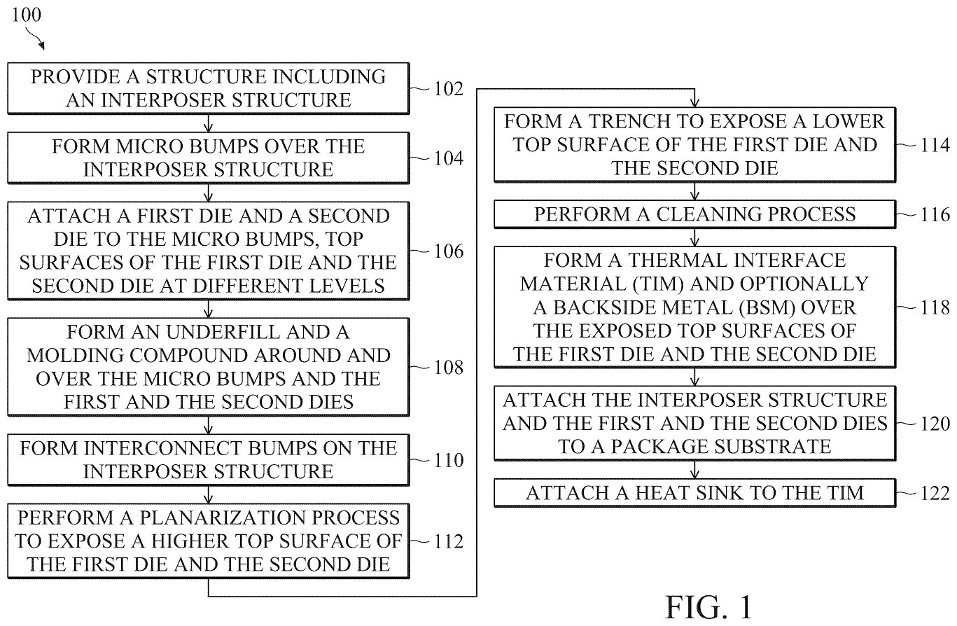

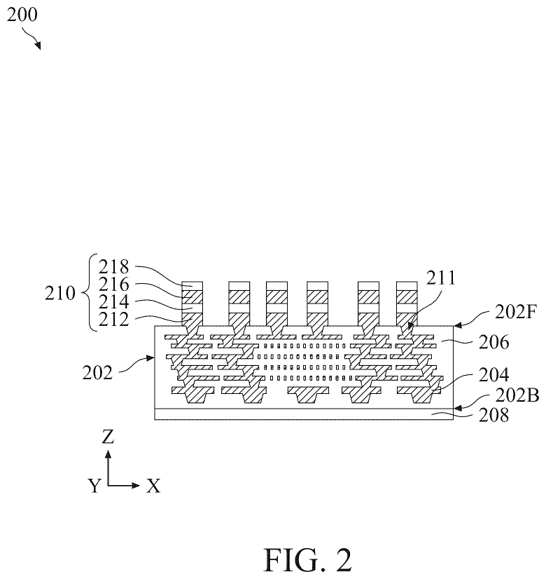

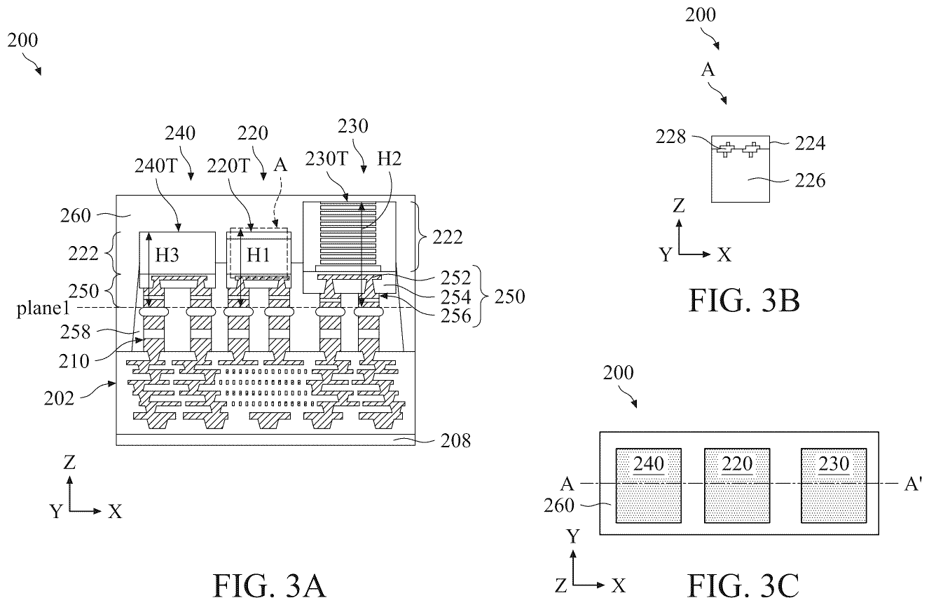

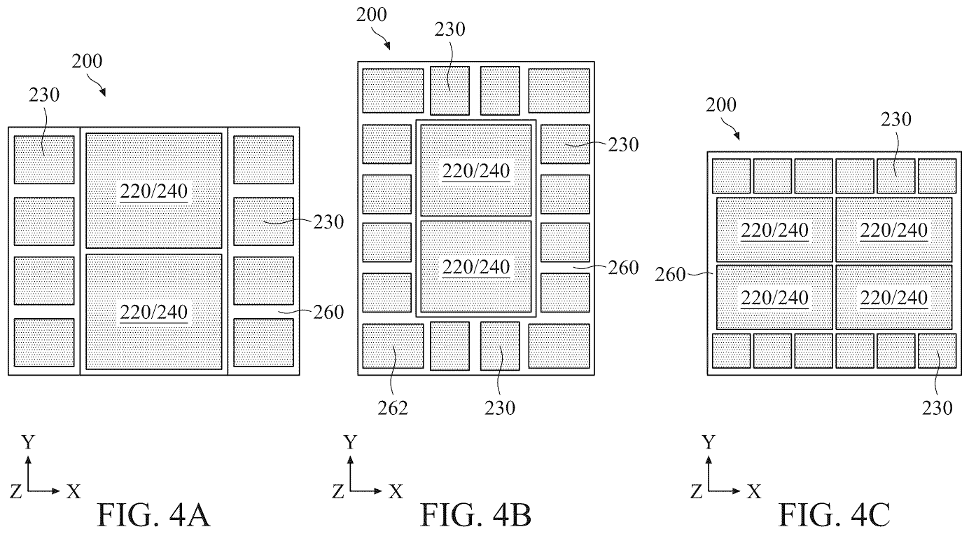

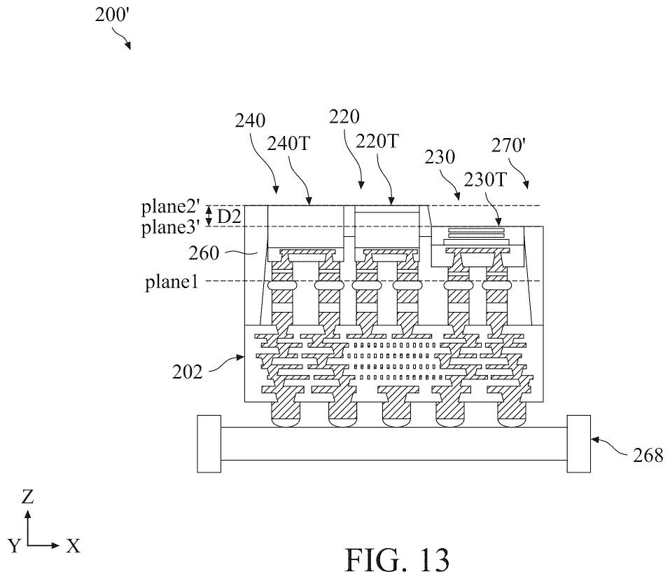

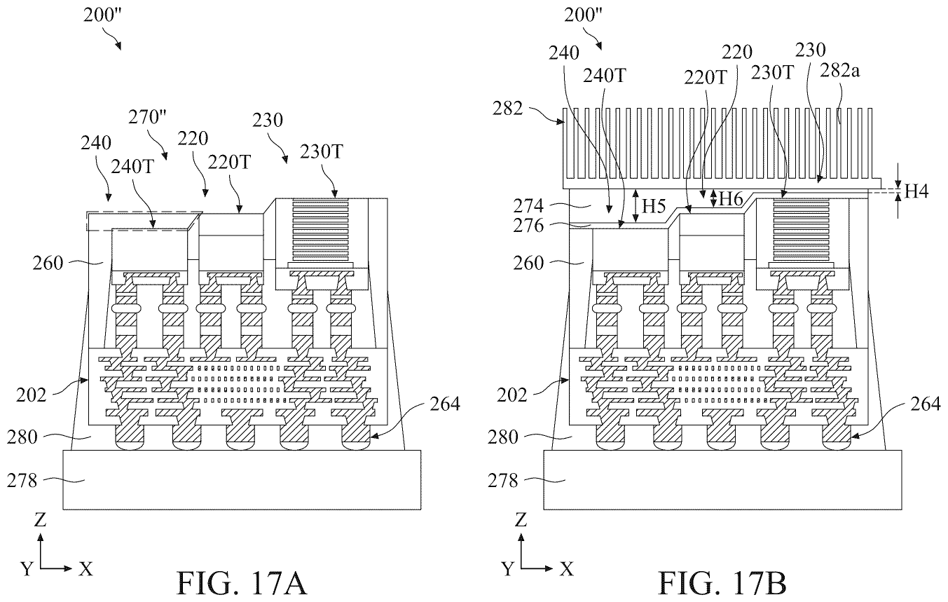

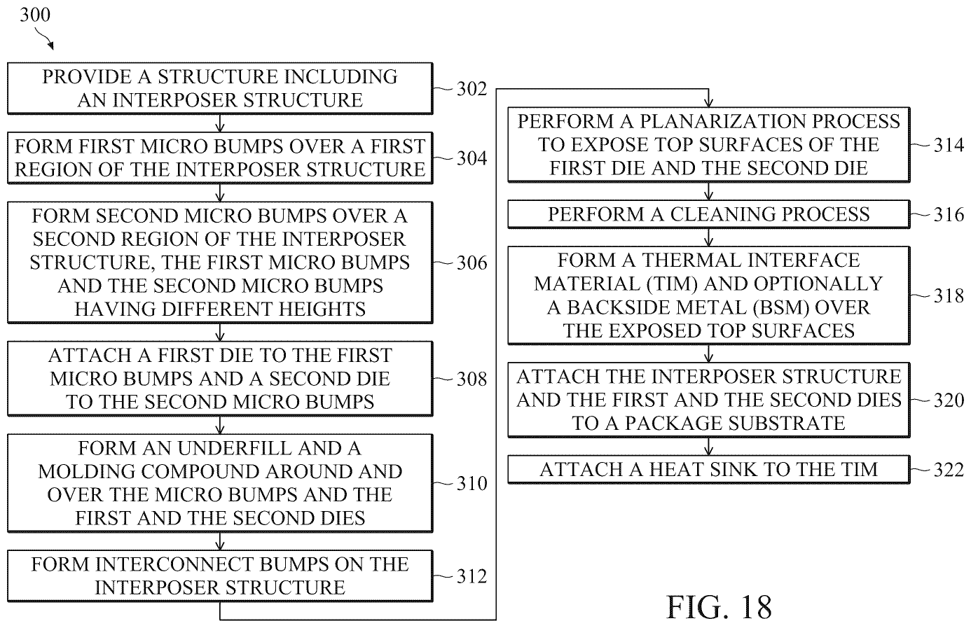

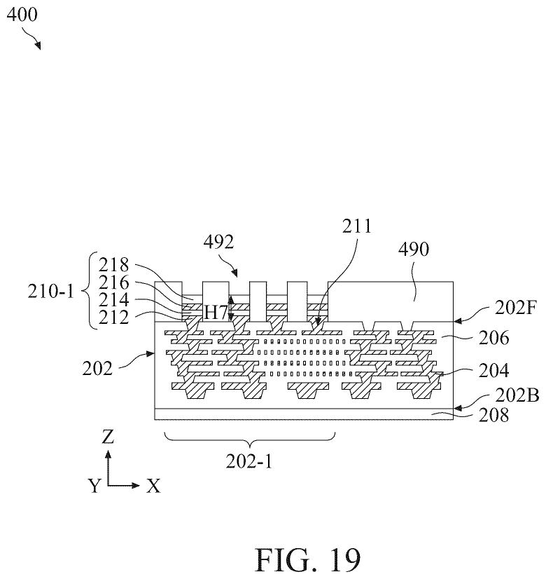

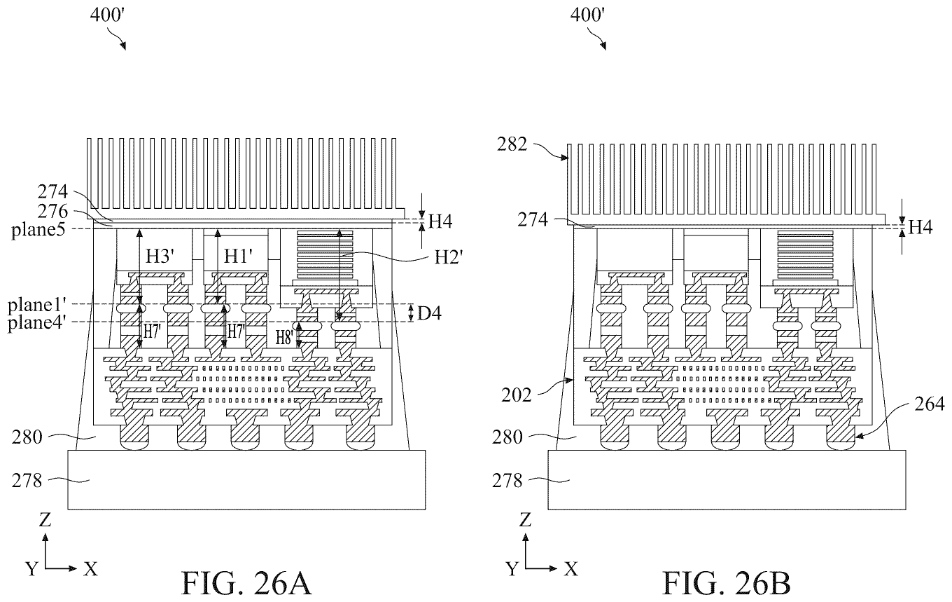

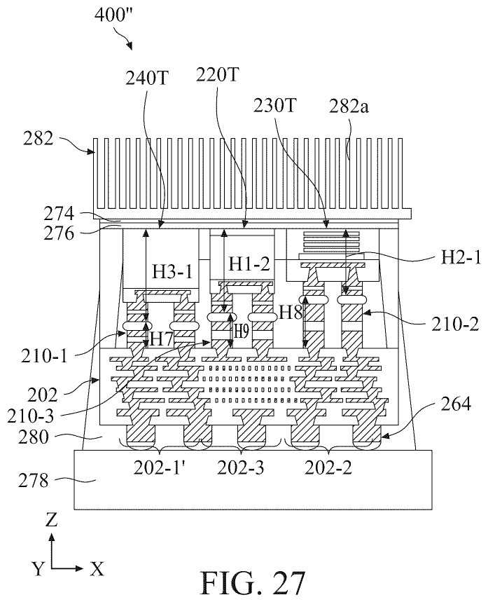

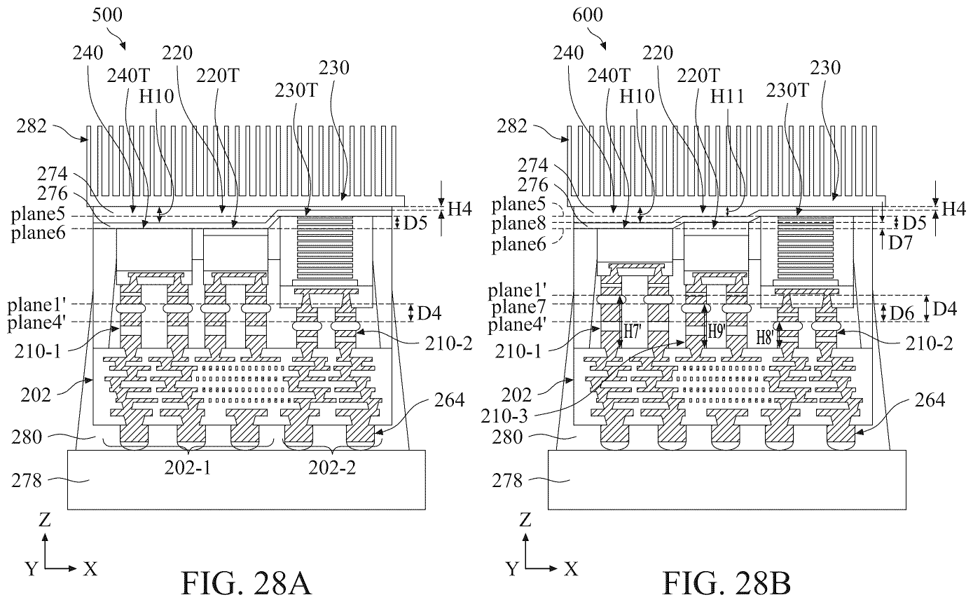

The various aspects of the present disclosure will now be described in more detail with reference to the figures. In that regard, FIG. 1 is a flowchart illustrating method 100 of forming a semiconductor package structure according to embodiments of the present disclosure. Method 100 is described below in conjunction with FIGS. 2-17B. FIGS. 2, 3A-3B, and 5-12B are fragmentary perspective or cross-sectional views of a structure 200 at different stages of fabrication according to embodiments of method 100 in FIG. 1. FIG. 3C is a fragmentary schematic top view of the structure 200 fabricated according to method 100 of FIG. 1, according to various aspects of the present disclosure. FIGS. 4A-4C are alternative fragmentary schematic top views of the structure 200, according to various aspects of the present disclosure. FIGS. 13-16B are fragmentary perspective or cross-sectional views of an alternative structure 200′ at different stages of fabrication according to embodiments of method 100 in FIG. 1. FIGS. 17A and 17B are cross-sectional views of an alternative structure 200″ at different stages of fabrication according to embodiments of method 100 in FIG. 1. FIG. 18 is a flowchart illustrating method 300 of forming a semiconductor package structure according to embodiments of the present disclosure. Method 300 is described below in conjunction with FIGS. 19-27. FIGS. 19-25B are fragmentary cross-sectional views of a structure 400 at different stages of fabrication according to embodiments of method 300 in FIG. 18. FIGS. 26A-26B are fragmentary cross-sectional views of an alternative structure 400′ at different stages of fabrication according to embodiments of method 300 in FIG. 18. FIG. 27 is a fragmentary cross-sectional view of an alternative structure 400″ at different stages of fabrication according to embodiments of method 300 in FIG. 18. FIGS. 28A-28B are fragmentary cross-sectional views of alternative structures 500 and 600, respectively, at different stages of fabrication according to embodiments of method 100 in FIG. 1 and method 300 in FIG. 18. Method 100 (or 300) is merely an example and is not intended to limit the present disclosure to what is explicitly illustrated in method 100 (or 300). Additional steps can be provided before, during and after method 100 (or 300), and some steps described can be replaced, eliminated, or moved around for additional embodiments of method 100 (or 300). Not all steps are described herein in detail for reasons of simplicity. Because the structure 200 (or 200′, 200″, 400, 400′, 400″, 500, 600) will be fabricated into a semiconductor package structure, the structure 200 (or 200′, 200″, 400, 400′, 400″, 500, 600) may be referred to herein as a semiconductor package structure 200 (or 200′, 200″, 400, 400′, 400″, 500, 600), a package structure 200 (or 200′, 200″, 400, 400′, 400″, 500, 600), or an IC package structure 200 (or 200′, 200″, 400, 400′, 400″, 500, 600) as the context requires. For avoidance of doubts, the X, Y and Z directions in FIGS. 2-17B and 19-28B are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1 and 2, method 100 includes a block 102 where a structure 200 including an interposer structure (e.g., an interposer 202) is provided. The interposer structure generally refers to a redistribution layer (RDL) structure that electrically connects one or more dies (to be described below) to each other and/or to another structure (e.g., a package substrate, to be described below). The interposer 202 may be a silicon interposer or an organic interposer. The interposer 202 may include conductive traces 204 that route electrical signals between dies and/or between dies and the package substrate. The conductive traces 204 may include various metal lines extending laterally and various metal vias extending vertically. The metal vias vertically connects the metal lines. The conductive traces 204 are embedded in a passivation structure 206 including one or more passivation layers. The passivation layers are insulating layers for isolating different signal paths (such as vias, metal lines, and/or landing pads) and may include a semiconductor material, an organic material such as a polymer, and/or glass. In some embodiments, the passivation layers include silicon (Si), silicon germanium (SiGe), or silicon carbon (SiC). In some embodiments, the passivation layers include a dielectric material.

A back side 202B of the interposer 202 is bonded to a first carrier substrate 208. The first carrier substrate 208 may be a silicon substrate. The interposer 202 may be temporarily bonded to the first carrier substrate 208 for structural support, and the first carrier substrate 208 may be debonded in a later step.

Still referring to FIGS. 1 and 2, method 100 includes a block 104 where micro bumps 210 are formed on a front side 202F of the interposer 202 and may be electrically connected to the conductive traces 204. The micro bumps 210 are for bonding to other external structures (e.g., dies). The micro bumps 210 may include multiple conductive layers, such as a copper (Cu) layer 212, a nickel (Ni) layer 214, a Cu layer 216, and a solder bump 218 (e.g., a lead-free solder bump) as depicted. The Ni layer 214 may be replaced by a cobalt-iron (CoFe) layer, etc. The solder bump 218 may include an electrically conductive solder material, e.g., tin (Sn), Ni, gold (Au), silver (Ag), Cu, bismuthinite (Bi) and alloys thereof, or combinations of. For example, the solder bump 218 may be a Cu/SnAg solder bump or a lead-free SnAg solder bump. A photoresist mask may be formed over the interposer 202 and patterned to form trenches where the micro bumps 210 are formed. The micro bump 210 may be formed by initially forming a Cu layer 212 through methods such as sputtering, evaporation, electroplating, printing, solder transfer, electrochemical deposition (ECD), or ball placement, followed by forming the Ni layer 214, the Cu layer 216, and finally followed by forming the solder bump 218, formed in sequence using the same or similar method for each layer. The micro bumps 210 may be formed simultaneously and have a similar height of about 10 μm to about 300 μm.

The micro bump 210 may be placed on an under-bump metal (UBM) pad 211 of the interposer 202, sometimes referred to herein as a contact pad 211. The UBM pad 211 may fill an opening or partially filling an opening of the passivation structure 206. The UBM pad 211 is connected to the conductive traces 204.

Referring to FIGS. 1 and 3A-3C, method 100 includes a block 106 where dies (e.g., device dies) are attached to the interposer 202 by the micro bumps 210. FIG. 3B is an enlarged view of a portion A in FIG. 3A. FIG. 3C illustrates a fragmentary schematic top view of the structure 200, and FIG. 3A is a fragmentary cross-sectional view of the structure 200 along line A-A′ in FIG. 3C. In the depicted embodiment in FIG. 3A, device dies 220, 230, and 240 are attached to the interposer 202. Each of the device dies 220, 230, and 240 includes a die portion 222 and a connecting structure 250 thereunder. The connecting structure 250 includes conductive paths 252, an insulation layer 254 surrounding the conductive paths 252, and upper micro bumps 256. The insulation layer 254 may include a dielectric material, such as an organic material (e.g., a polymer). The upper micro bumps 256 include multiple conductive layers, such as a Cu layer, a Ni layer, and a Cu layer similar to those in the micro bumps 210 and may be formed by similar methods as the micro bumps 210. A reflow process is performed such that the micro bumps 210 electrically connect the interposer 202 to upper micro bumps 256 of the device dies.

The device dies including the device dies 220, 230, and 240 may be of any types. The device dies may include a System-on-Chip (SoC) die, a System-on-Integrated-Chips (SoIC) die, a high bandwidth memory (HBM) die, an application specific integrated circuit (ASIC) die (e.g., a neural processing unit (NPU), a data processing unit (DPU)), a DRAM die, a logic die, a customized die, or a combination thereof. In some embodiments, the device die 240 is a SoC die. An SoC die may include a memory controller that interfaces the HBM dies and a graphic processing unit (GPU), a central processing unit (CPU), or a neural processing unit (NPU). The memory controller is normally built-in in the SoC die and that is why the SoC die is referred to as “System-on-Chip.” In some embodiments, the device die 220 is a SoIC die. A SoIC die may be a composite die having multiple dies vertically stacked. Referring to FIG. 3B, the device die 220 may include a top die 224, a bottom die 226, and a bonding feature 228 (e.g., through silicon vias (TSVs)) connecting the top die 224 and the bottom die 226. In some embodiments, the device die 230 is a HBM die. HBM is a computer memory interface that is commonly used in conjunction with high-performance graphics accelerators, high-performance data center, ASIC for AI application, on-package cache in CPUs, or high-performance computing ICs. An HBM die (e.g., the device die 230) may include a vertical stack of memory dies, such as DRAM dies. In some instances, an HBM die may include a plurality of DRAM dies, such as 2 to 16 DRAM dies stacked together. The vertical stacking allows for higher bandwidth, smaller power consumption, and smaller form factor. HBM has been accepted as an industry standard. The HBM dies (e.g., the device die 230) include HBM dies with all current and future generations of HBM standards.

The device dies may have different heights. For example, the device dies 220, 230, and 240 have heights H1, H2, and H3, respectively, as depicted. In some embodiments, H2 is greater than H1 and H3. H1 may be the same as or different from H3. In the embodiments where the micro bumps 210 have a same height, the connecting structures 250 of the device dies may have bottoms surfaces at a same level (e.g. as in plane 1). Thus, a top surface 230T of the device die 230 is higher than top surfaces 220T and 240T of the device die 220 and the device die 240.

The device dies may be formed in a separate manufacturing process that includes forming device structures on a wafer and dicing the wafer into chips. The chips may then be processed to form the different device dies.

Still referring to FIGS. 1 and 3A-3C, method 100 includes a block 108 where an underfill 258 and a molding compound 260 are formed to provide structural integrity and to improve stress absorption. The underfill 258 may be formed over the interposer 202 and around the micro bumps 210 and bottom portions of the device dies (e.g., 220, 230, 240). The underfill 258 may include polymer or epoxy. The molding compound 260 may also be referred to as an encapsulation layer 260. The molding compound 260 may be formed over the device dies, the interposer 202, and the underfill 258. The molding compound 260 may surround the device dies as depicted in FIG. 3C. The molding compound 260 may include a base material and fillers embedded in the base material. In some implementations, the base material of the molding compound 260 may include polymer, resin or epoxy and the fillers may include spherical particles of silicon oxide (silica) or aluminum oxide. The molding compound 260 may be deposited over the structure 200 and thinned by a first planarization process, such as a grinding or a mechanical chemical grinding (MCG) process. In the depicted embodiment, the top surfaces 220T, 230T, and 240T of the device dies 220, 230, 240 are covered by the molding compound 260.

In FIG. 3C, the device dies 220, 230, and 240 are arranged along the X-direction. However, it is understood that the arrangement of the device dies 220, 230, and 240 is not limited to that shown in FIG. 3C, and may have any suitable arrangement (e.g., in a top view). The structure 200 may include any suitable number and types of the device dies. FIGS. 4A-4C illustrate example alternative fragmentary schematic top views of the structure 200. As shown, various device dies (e.g., 220, 230, 240), are located in a die area of the structure 200. In the depicted embodiment, the device dies 220 or 240 (e.g., SoC/SoIC dies) are located towards the center area of the die area, and the device dies 230 (e.g., HBM dies) are located in the peripheral area of the die area, but the present disclosure is not limited thereto. In the depicted embodiment as in FIG. 4A, the device dies 220 or 240 (220/240) are arranged along the Y-direction and are sandwiched by the device dies 230 along the X-direction. In the depicted embodiment as in FIG. 4B, the device dies 220 or 240 are arranged along the Y-direction and are sandwiched by the device dies 230 along the X-direction and along the Y-direction, and the structure 200 further includes dies 262 that may be dummy dies (e.g., dies not including devices) or logic dies in corners. In the depicted embodiment as in FIG. 4C, the device dies 220 or 240 are arranged in a matrix sandwiched by the device dies 230 along the Y-direction.

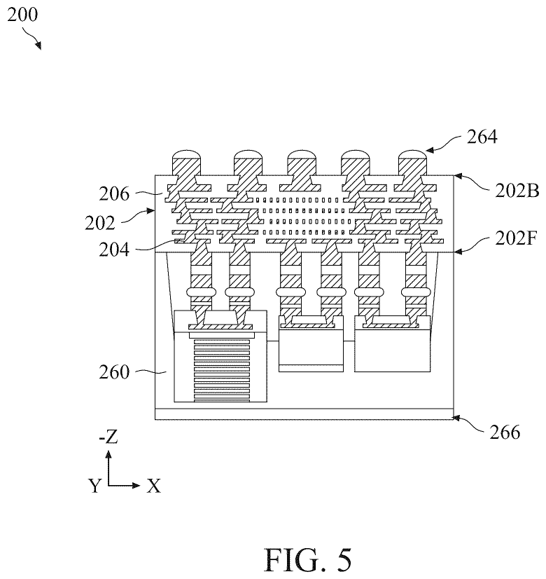

Referring to FIGS. 1 and 5, method 100 includes a block 110 where interconnect bumps 264 (also referred to as controlled collapse chip connection (C4) bumps 264) are formed on the back side 202B of the interposer 202 and electrically connected to the conductive traces 204. The C4 bumps 264 may include solder bumps or copper pillar (CuP) bumps. The solder bumps may include tin, lead, and/or silver, and the CuP bumps may include a copper pillar having a solder cap at the end. The solder cap may be made of tin, lead, and/or silver. Before forming the C4 bumps 264, the first carrier substrate 208 (shown in FIG. 3A) is debonded, the workpiece 200 may be flipped over, and the molding compound 260 may be temporarily bonded to a second carrier substrate 266 (e.g., a silicon substrate) for structural support. The second carrier substrate 266 may be debonded in a later step. The operations may include thinning down (e.g., by MCG, grinding, etching) the interposer 202 from the back side 202B to expose the conductive traces 204 and forming the C4 bumps 264 on the conductive traces 204. Landing pads may be formed to connect the conductive traces 204 and the C4 bumps 264. The C4 bumps 264 may be formed by initially forming one or more conductive layers through any suitable method such as evaporation, electroplating, printing, solder transfer, ball placement, etc. A reflow process may then be performed in order to shape the C4 bumps 264 into the desired bump shape.

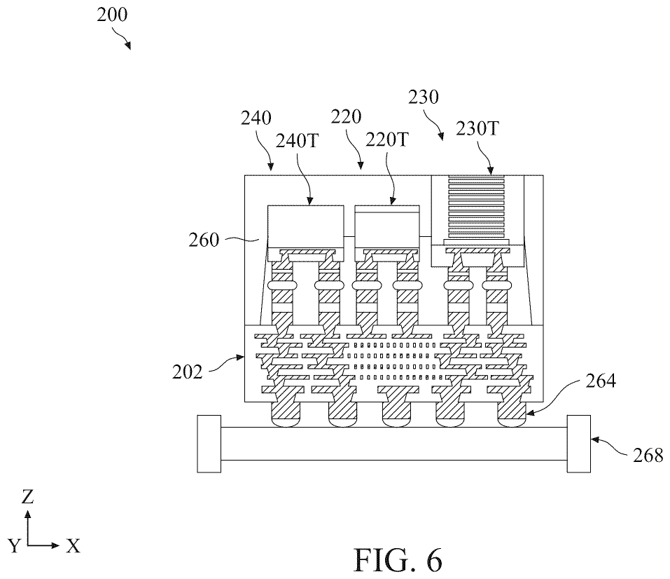

Referring to FIGS. 1 and 6, method 100 includes a block 112 where a second planarization process (e.g., a grinding or an MCG process), is performed to expose a higher top surface (e.g., the top surface 230T of the second device die 230) compared to the other top surface(s) of the device dies. In the depicted embodiment, the top surfaces 220T and 240T of the device dies 220 and 240 remain covered by the molding compound 260. Before the second planarization process, the C4 bumps 264 of the structure 200 may be bonded to a support structure 268 for structural support. The support structure 268 may include a frame-and-tape structure or a third carrier substrate.

Referring to FIGS. 1 and 7-9, method 100 includes a block 114 where a trench 270 is formed by a local thinning process to expose the lower top surface(s) (e.g., the top surfaces 220T and 240T of the device died 220 and 240) of the device dies. The local thinning process may include a grinding process (e.g., a grinding or an MCG process) performed over the device dies 220 and 240. The local thinning process may not grind the top surface 230T. A portion of the molding compound 260 may remain on a sidewall of the device die 230. In the embodiments where the top surfaces 220T and 240T before operations at block 114 are at a same level, the local thinning process may only remove a portion of the molding compound 260 over the device dies 220 and 240. In some other embodiments, the top surfaces 220T and 240T are at different levels before operations at block 114. In such embodiments, the local thinning process may further remove a top portion of the device die 220 or the device die 240, whichever having a higher top surface before block 114, without damaging the device therein. An inline or offline monitor for statistical process control (SPC) with defect inspection compatibility may be used in the local thinning process. The top surfaces 220T and 240T upon completion of operations at block 114 may be at a same level (e.g., as of plane 2). As depicted, the top surface 230T is at a higher level (e.g., as of plane 3). A distance D1 between plane 3 and plane 2 may be about 10 μm to about 500 μm.

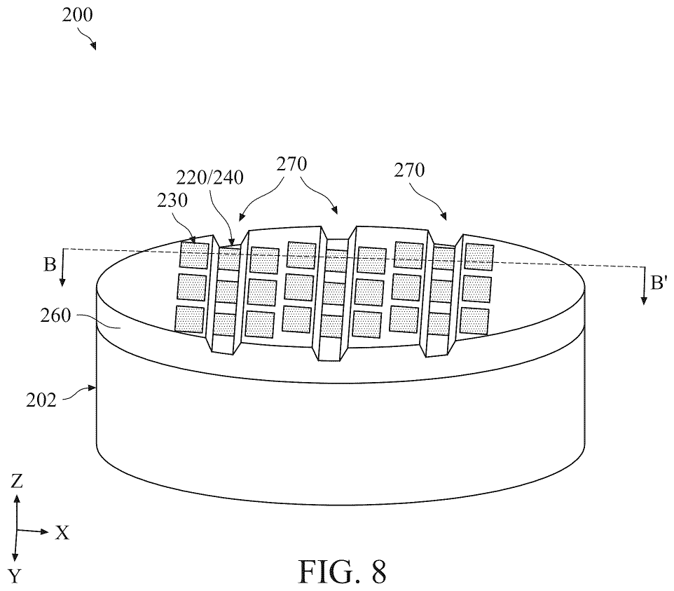

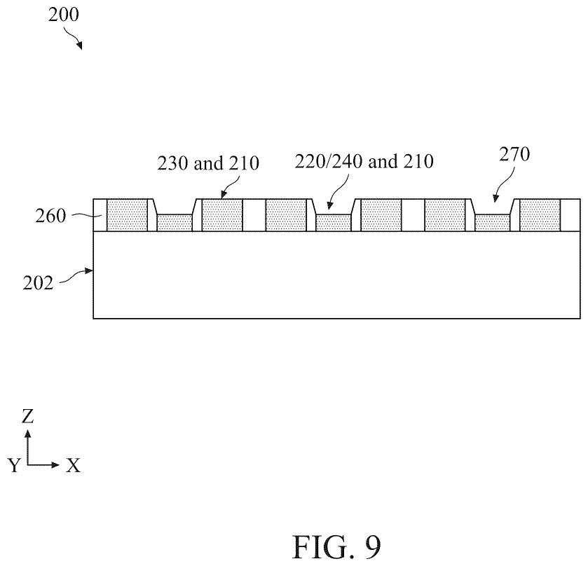

FIG. 8 illustrates an alternative fragmentary perspective view of the structure 200. FIG. 9 illustrates a fragmentary schematic cross-sectional view of the structure 200 taken along line B-B′ as in FIG. 8. Referring to FIGS. 8 and 9, the structure 200 includes arrays of device dies 230 and the device dies 220 or 240 (220/240). The operations at block 114 may form a plurality of the trenches 270, in which the top surfaces of the device dies 220/240 are exposed. In the depicted embodiment, the trenches 270 are in parallel to each other. In the depicted embodiment, the trenches 270 have the same depth. In some other embodiments, the trenches 270 have different depth and may be formed in a series of local thinning processes.

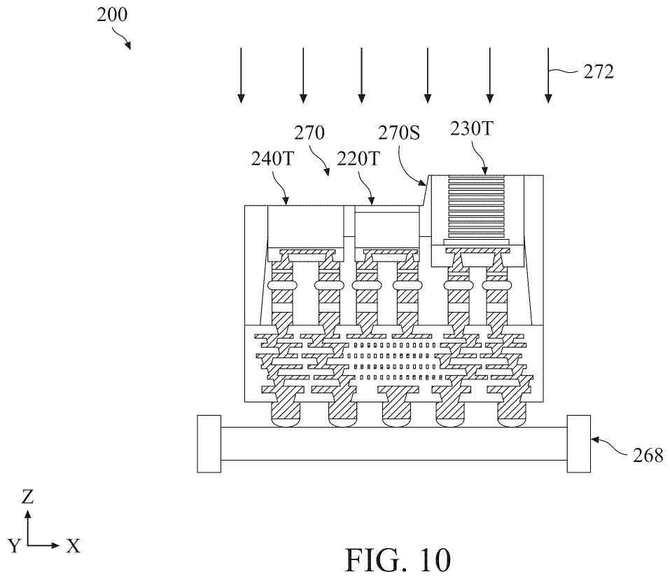

Referring to FIGS. 1 and 10, method 100 includes a block 116 where a cleaning process 272 (e.g., a wet clean and/or a dry clean) is performed to the structure 200. Deionized water, ultra deionized water, isopropyl alcohol (IPA), air, compressed air, or a combination thereof may be used in the cleaning process 272. Contaminants (e.g., particles) may be removed from the surfaces (e.g., top surface 220T, sidewall 270S) of the structure 200.

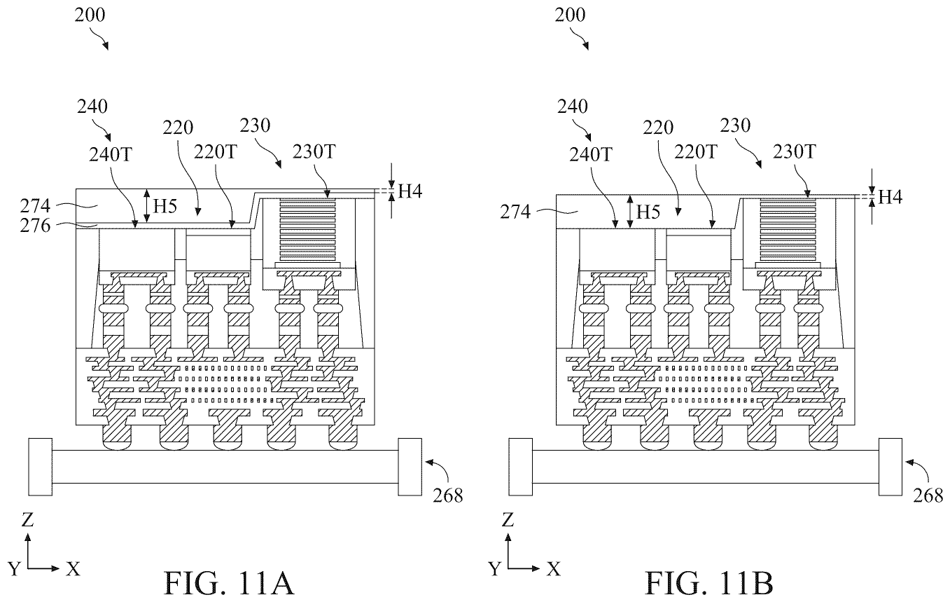

Referring to FIGS. 1 and 11A-11B, method 100 includes a block 118 where a thermal interface material (TIM) 274 and optionally a backside metal (BSM) structure 276 are formed over the exposed top surfaces (e.g., 220T, 230T, and 240T) of the device dies. In some embodiment as depicted in FIG. 11A, the BSM structure 276 is formed on the top surfaces (e.g., 220T, 230T, 240T) of the device dies and sidewall(s) 270S of the trench 270 (shown in FIG. 10). Then the TIM 274 is formed over the BSM structure 276. In some other embodiments as in FIG. 11B, the BSM structure 276 is omitted, and the TIM 274 is formed on the top surfaces (e.g., 220T, 230T, 240T) of the device dies and sidewall(s) 270S of the trench 270 (shown in FIG. 10). Because the molding compound 260 (shown in FIG. 6) over the device dies 220 and 240 are removed, the top surfaces of the device dies (e.g., 220 and 240) directly contact the TIM 274 or the BSM structure 276, which have greater thermal conductivity than the molding compound 260. Thus, heat dissipation efficiency may be improved. With increase heat dissipation, the structure 200 may accommodate increased device density, scalability, and flexibility of designs.

The BSM structure 276 may include a metal or a metal alloy, such as a metal alloy including titanium (Ti), Au, Cu, Ni, vanadium (V), aluminum (Al), Ag, Sn, or a combination thereof. The BSM structure 276 may have a thickness of about 10 nm to about 20 μm. The BSM structure 276 may be conformally deposited and have a uniform thickness.

For purpose of the present disclosure, TIM refers to materials that are placed between an electronic device and a heat sink (to be described below) to improve heat dissipation of the electronic device. TIM or a precursor of TIM may possess reasonable flowability or flexibility. Additionally, TIM may have sufficient thermal conductivity to facilitate heat conduction. Furthermore, it is desirable that TIM has good stress absorption property to protect the electric device and prevent delamination. The TIM 274 may be applied in a gel form or a liquid form. The TIM 274 may include a metal or a metal alloy. In some embodiments, the TIM 274 includes indium (In), Ag, Cu, a gallium alloy, zinc oxide (ZnO), aluminum nitride (AlN), or a combination thereof. In some embodiments, a first portion of the TIM 274 over the device die 230 may have a thickness H4 of about 2 μm to about 50 μm. A second portion of the TIM 274 over the device dies 220 and 240 may have a thickness H5 of about 10 μm to about 500 μm. H5 may be greater than H4 as depicted. Depending on the types of the TIM 274, the TIM 274 may be attached to the BSM structure 276 through picking and placing or dispensing process.

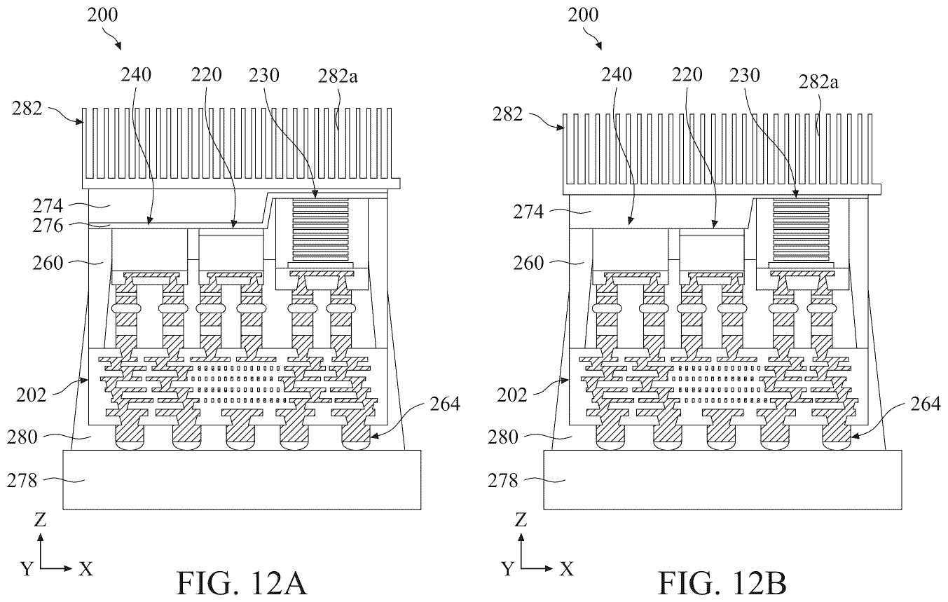

Referring to FIGS. 1 and 12A-12B, method 100 includes a block 120 where the interposer 202 and the device dies are attached to a package substrate 278. The support structure 268 (shown in FIGS. 11A-11B) are debonded from the C4 bumps 264. The interposer 202 may be attached via the C4 bumps 264 landing on and bonding to landing pads (not depicted) of the package substrate 278. Thereafter, as part of operations of block 120, the method 100 may form an underfill (e.g., underfill 280) to fill gaps between the interposer 202 and the package substrate 278. The underfill 280 may laterally surround the C4 bumps 264, the interposer 202, and a bottom portion of the molding compound 260.

The package substrate 278 generally refers to a wafer or semiconductor structure that acts as a carrier base for an IC package. This carrier base may also be generally referred to as a base substrate, a substrate underlayer, or the like. In an embodiment, the package substrate 278 includes a semiconductor substrate formed of silicon, silicon germanium, silicon carbon, or the like. The package substrate 278 may have various package components mounted thereon, such as one more interposers 202, one or more dies (e.g., the device dies 220, 230, 240), and/or one or more other active or passive chip devices such as one or more surface mount (SMT) components (not depicted). The SMT components may be SMT capacitors. The package substrate 278 may further include redistribution layers formed therein, and the redistribution layers route signals from die components (e.g., the device dies 220, 230, 240) and chip devices (e.g., SMT components) onto a printed circuit board (PCB) (not shown).

Still referring to FIGS. 1 and 12A-12B, method 100 includes a block 122 where a heat sink 282 (e.g., a heat-spreading lid, a metal lid) is attached to the TIM 274. the heat sink 282 may act as a cap or cover. The heat sink 282 absorbs and dissipates any heat coming from components of the device dies therebelow. For example, the heat sink 282 absorbs heat from the device dies through the TIM 274 and optionally the BSM structure 276. The heat sink 282 may directly contact the TIM 274. The heat sink 282 may be formed of a metal or a metal alloy having a thermal conductivity of higher than about 100 W/m/K. For example, the heat sink 282 may be formed of a metal, or a metal alloy selected from Al, Cu, Ni, Co, stainless steel, and alloys thereof. The heat sink 282 may include elongated protrusions (e.g., pin fins) 282a that protrude upwards from a top surface of the heat sink 282. The elongated protrusions 282a offer improved heat dissipation and cooling to cool down the heat sink 282. A coolant (e.g., air, water, not depicted) may be circulated over the heat sink 282 and among the elongated protrusions 282a. The elongated protrusions 282a may be formed before the operations of block 122. The heat sink 282 is placed over (e.g., pushed down against) the TIM 274 and may be mounted to the package substrate 278 by mechanical joints (not depicted, e.g., screws).

The structure 200 may undergoes further process. The structure 200 may be part of a bigger IC structure. For example, the structure 200 may be mounted onto a PCB (not depicted) therebelow. In this case, the package substrate 278 may include a ball-grid array (BGA) structure (not depicted) on its back side. The BGA structure includes solder joints. One or more of the structures 200 may be bonded onto the PCB by BGA structures. The PCB may include multiple other IC components mounted thereon, thereby forming a processor, a controller, a memory unit, or other electronic modules.

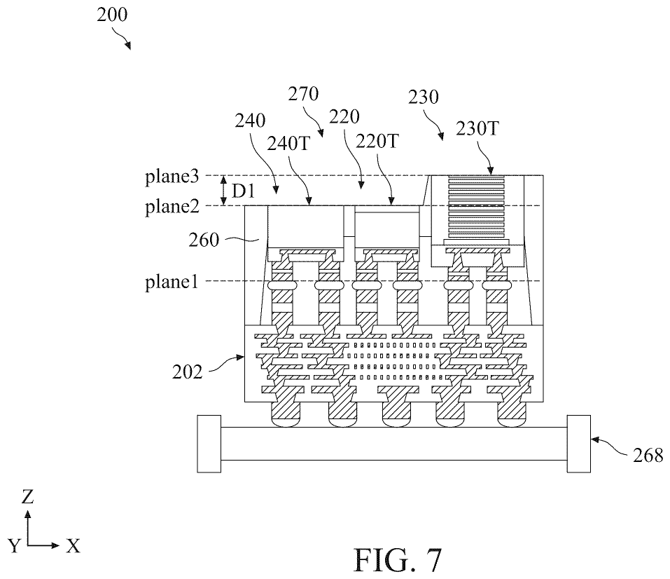

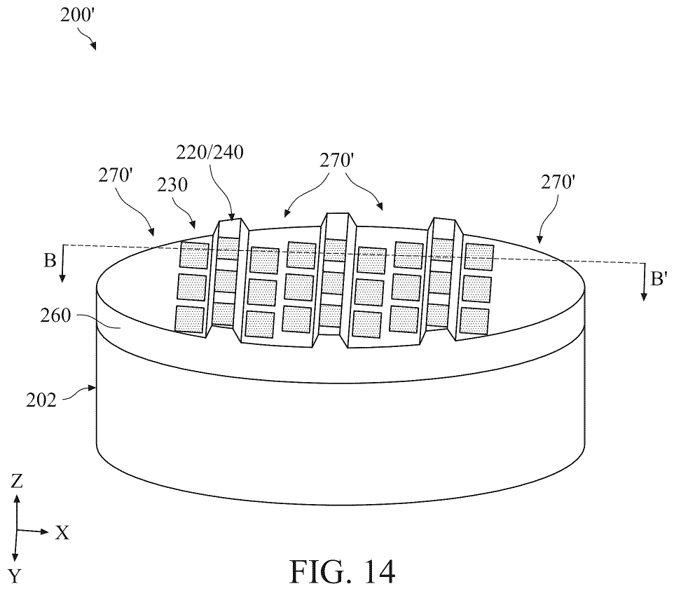

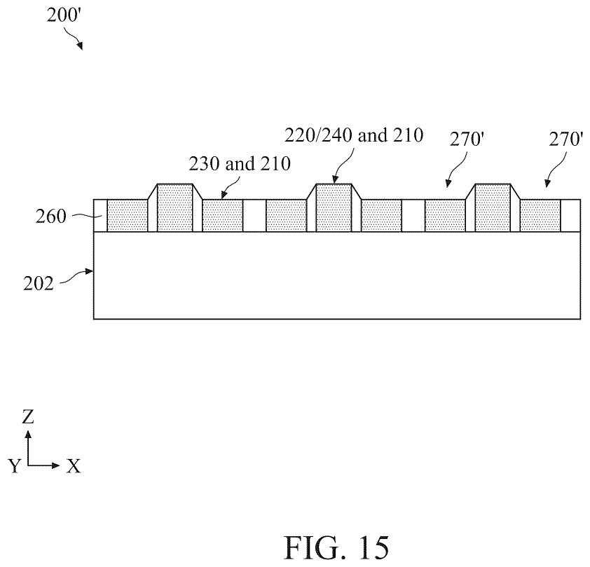

Referring to FIGS. 1 and 13-16B, an alternative structure 200′ may be fabricated according to method 1 of FIG. 1. The structure 200′ undergoes operations at blocks 102 to 114 of method 1 and FIG. 13 illustrates a fragmentary cross-sectional view of the structure 200′ upon completion of the operations at block 114. FIG. 14 illustrates an alternative fragmentary perspective view of the structure 200′. FIG. 15 illustrate a fragmentary schematic cross-sectional view of the structure 200′ taken along line B-B′ as in FIG. 14. Differences from the structure 200 and the fabrication of the structure 200 include the follows. In the structure 200′, the device dies 220 and 240 have greater heights than the device die 230, and the top surfaces 220T and 240T are higher than the top surface 230T. At block 112, instead of exposing the top surface 230T (shown in FIG. 6), the top surfaces 220T and 240T of the structure 200′ are exposed as in FIG. 13. A top portion of the device die 220 or the device die 240 in the structure 200′ may be removed without damaging the devices therein as a part of the operations at block 112. At block 114, instead of forming the trench(s) 270 (shown in FIGS. 7-9), trench(s) 270′ are formed to expose the top surface(s) 230T. Referring to FIG. 13, the top surfaces 240T and 220T are at a same level (e.g., as in plane 2′), and the top surface 230T is at a lower level (e.g., as in plane 3′). A distance D2 between plane 2′ and plane 3′ may be about 10 μm to about 500 μm. Referring to FIGS. 14-15, the top surfaces of the device dies 230 are exposed in a plurality of the trenches 270′. In the depicted embodiment, the trenches 270′ are in parallel to each other. In the depicted embodiment, the trenches 270′ have the same depth. In some other embodiments, the trenches 270′ have different depth and may be formed in a series of local thinning processes.

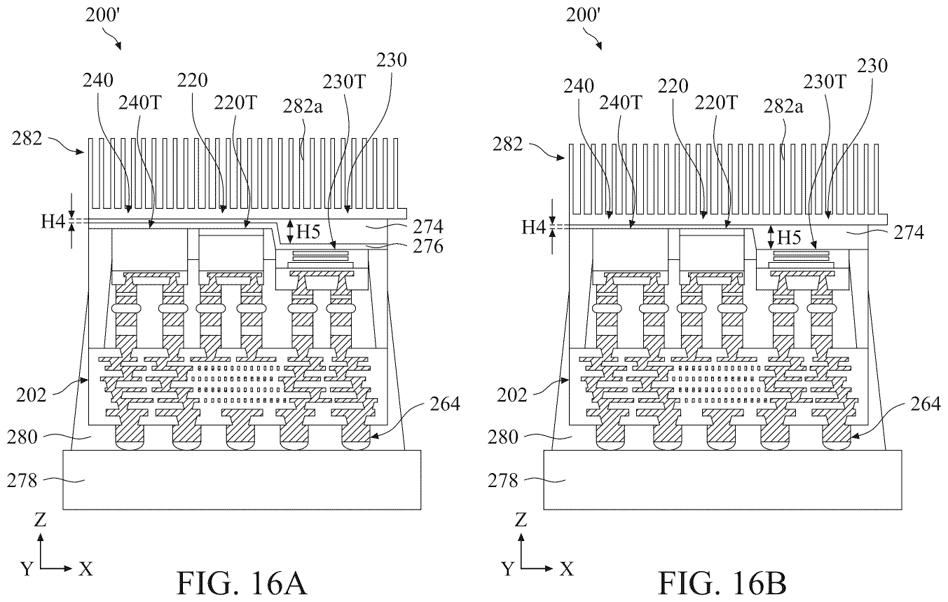

The structure 200′ then undergoes operations at blocks 116 to 122 of method 100 and the resulting structure 200′ is illustrated in FIGS. 16A-16B. The differences from the structure 200 and the fabrication of the structure 200 further include that, in the structure 200′, because the top surfaces 220T and 240T of the device dies 220 and 240 are higher than the top surface 230T of the device die 230, a first portion of the TIM 274 over the device dies 220 and 240 have the thickness H4 as described above, and a second portion of the TIM 274 over the device die 230 has the thickness H5 as described above.

In some embodiments, the top surfaces of the device dies are at different levels. FIGS. 17A-17B illustrates fragmentary cross-sectional views of an example structure 200″ at different stages of fabrication according to embodiments of method 100 in FIG. 1. Differences from the structure 200 and the fabrication of the structure 200 include the follows. In the structure 200″, the top surface 220T is higher than the top surface 240T and lower than the top surface 230T. Referring to FIG. 17A, at block 112, a first local thinning process (e.g., a grinding or an MCG process) removes a portion of the molding compound 260 to form a trench 270″ to expose the top surface 220T but not the top surface 240T, and a remaining portion of the molding compound 260 remains on the top surface 240T as circled by the dashed lines. A second local thinning process (e.g., a grinding or an MCG process) is then performed as a part of operations at block 112 to extend the trench 270″ by removing the remaining portion of the molding compound 260 and to expose the top surface 240T. The extended trench 270″ includes the trench 270″ shown in FIG. 17A and the space circled by the dashed lines. In such embodiments, referring to FIG. 17B, the TIM 274 have three different thicknesses H4, H5, and H6 for portions above the device dies 230, 240, and 220, respectively, as depicted. H4 and H5 are as described above. H6 is between H4 and H5. H6 may be smaller than H5 by about 2 μm to about 490 μm. The BSM structure 276 may be omitted.

Referring to FIGS. 18 and 19, method 300 includes a block 302 where a structure 400 including an interposer 202 is provided. Operations at block 302 is similar to block 102 of method 100. Still referring to FIGS. 18 and 19, method 300 includes a block 304 where first micro bumps 210-1 are formed over a first region 202-1 of the interposer 202. The first micro bumps 210-1 may include similar materials and conductive layers 212, 214, 216, and 218 as the micro bumps 210 as described above. The first micro bumps 210-1 may have a height H7 as depicted. In some embodiments, operations at block 304 include forming (e.g., depositing) a photoresist layer 490, patterning (e.g., by photolithography, etching) the photoresist layer 490 to form trenches 492, forming the first micro bumps 210-1 in the trenches 492, and removing the patterned photoresist layer 490. In an example process, the photoresist layer 490 may be blanketly deposited over the structure 400, including over the interposer 202. The photoresist layer 490 is then exposed to radiation going through or reflected from a mask, baked in a post-bake process, and developed in a developer solution. An etching process may be performed to complete the forming of the trenches 492. The first micro bumps 210-1 may be formed by initially forming a Cu layer 212 through methods such as sputtering, evaporation, electroplating, printing, solder transfer, ECD, or ball placement, followed by forming the Ni layer 214, the Cu layer 216, and finally followed by forming the solder bump 218, formed in sequence using the same or similar method for each layer.

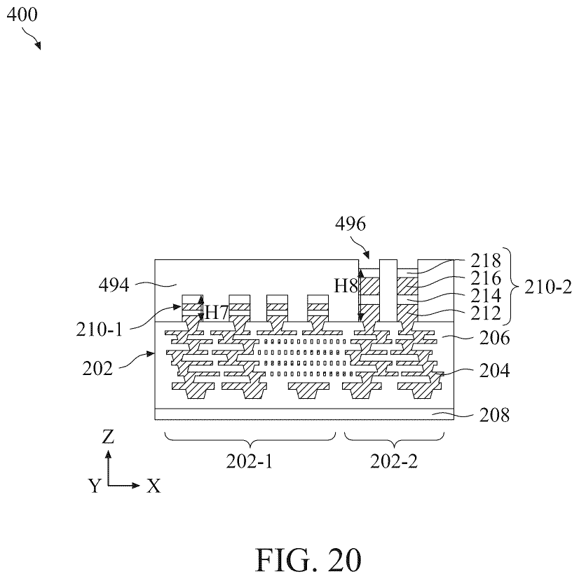

Referring to FIGS. 18 and 20, method 300 includes a block 306 where second micro bumps 210-2 are formed over a second region 202-2 of the interposer 202. The first micro bumps 210-1 and the second micro bumps 210-2 may be individually or collectively referred to as micro bump(s) 210, as the context requires. The second micro bumps 210-2 may include similar materials and conductive layers as the micro bumps 210 as described above. The second micro bumps 210-2 may have a height H8 as depicted. In the depicted embodiments, H8 is greater than H7. In some embodiments, operations at block 306 include forming (e.g., depositing) a photoresist layer 494 over the interposer 202 and the first micro bumps 210-1, patterning (e.g., by photolithography, etching) the photoresist layer 494 to form trenches 496, forming the second micro bumps 210-2 in the trenches 496, and removing the photoresist layer 494. Patterning the photoresist layer 494 and forming the second micro bumps 210-2 may involve processes similar to patterning the photoresist layer 490 and forming the first micro bumps 210-1 as described above.

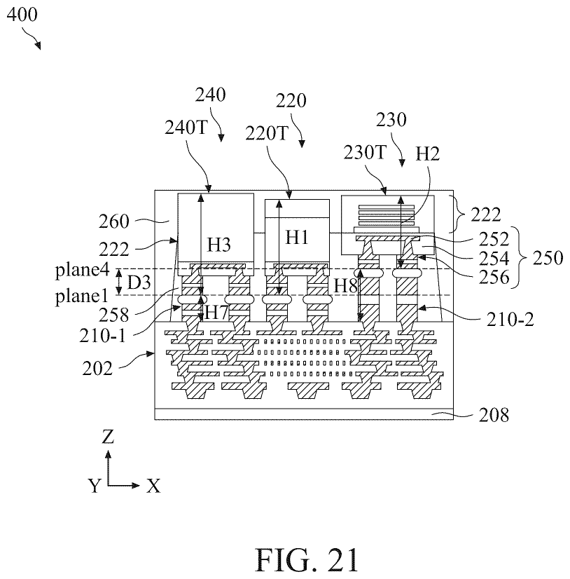

Referring to FIGS. 18 and 21, method 300 includes a block 308 where device dies 220 and 240 are bonded to the first micro bumps 210-1 and the device die 230 is bonded to the second micro bumps 210-2. Operations at block 308 are similar to that at block 106. In the depicted embodiment, the top surfaces (e.g., 220T, 230T, and 240T) of the device dies are at different levels. The differences between the different levels may be less than about 50 μm, alternatively less than about 10 μm. In some other embodiments, the top surfaces of the device dies are coplanar. The device dies may have different heights (e.g., H1, H2, H3). The die portions 222 may have different thicknesses. Elevation of the top surfaces 220T, 230T, and 240T to the levels described above may be achieved by adjusting heights (e.g., H7, H8) of the micro bumps 210 (e.g., the first micro bumps 210-1, the second micro bumps 210-2) and/or by adjusting heights of the upper micro bumps 256 of the device dies 220, 230, and 240. The first micro bumps 210-1 may have top surfaces at a level of plane 1, and the second micro bumps 210-2 may have top surfaces at a level of plane 4. In the depicted embodiments, a difference D3 between plane 1 and plane 4 is about 10 μm to about 200 μm. If D3 is too large, for example, greater than 200 μm, the micro bumps 210-2 may be too high, which may cause too much instability of the second micro bumps 210-2 and the device die 230 thereabove. If D3 is too small, for example, smaller than 10 μm, benefit of forming micro bumps with different heights may be too small compared to the cost associated therein. Differences between heights of the upper micro bumps 256 of different device dies may be less than about 200 μm, alternatively less than about 50 μm.

Still referring to FIGS. 18 and 21, method 300 includes a block 310 where an underfill 258 and a molding compound 260 are formed around and over the micro bumps 210 and the device dies 220, 230, and 240. Operations at block 310 are similar to that at block 108.

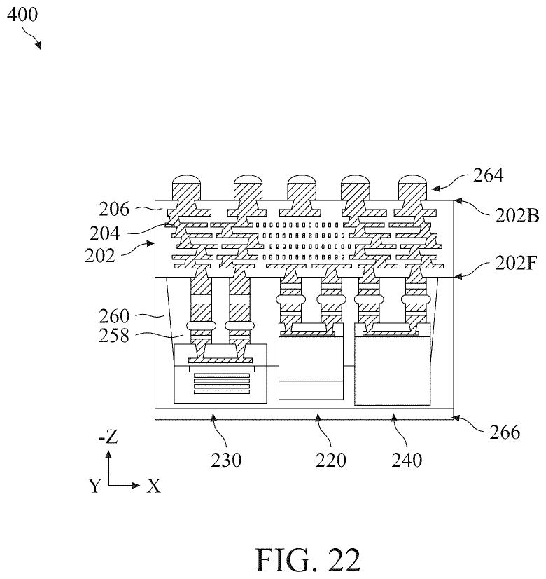

Referring to FIGS. 18 and 22, method 300 includes a block 312 where interconnect bumps 264 are formed on the back side 202B of the interposer 202. Operations at block 312 are similar to that at block 110.

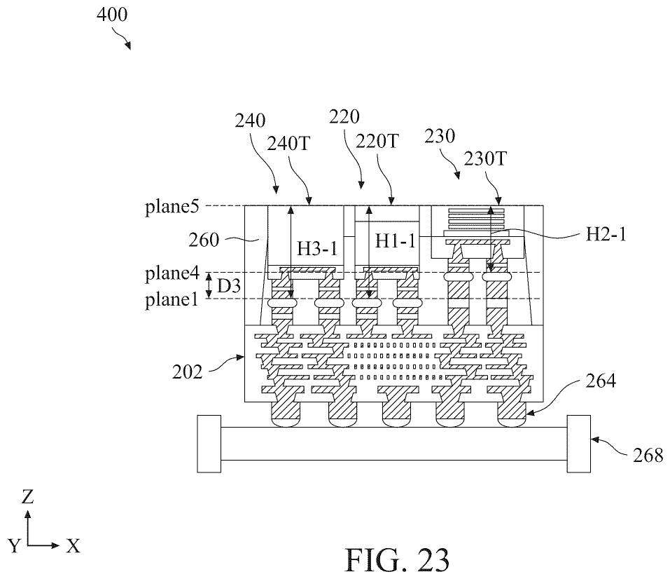

Referring to FIGS. 18 and 23, method 300 includes a block 314 where a planarization process (e.g., a grinding or an MCG process) is performed to expose top surfaces of the device dies (e.g., 220, 230, and 240). Compared to operations at block 112, a difference includes that the planarization process at block 314 exposes top surfaces of the device dies 220, 230, and 240. A top portion of the device dies 220, 230, and/or 240 may be removed in the planarization process without damaging the devices therein. After the planarization process, the top surfaces (e.g., 220T, 230T, and 240T) of the device dies 220, 230, and 240 may be coplanar (e.g., as in plane 5). The device dies 220, 230, and 240 may have heights of H1-1, H2-1, and H3-1, respectively, after the planarization process. H1-1 may be the same as H3-1 and greater than H2-1. H1-1, H2-1, and H3-1 may be the same as or different from H1, H2, and H3, respectively.

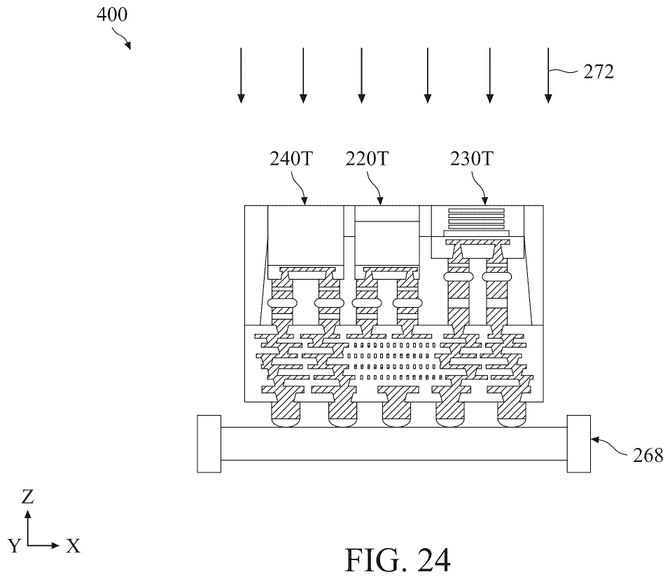

Referring to FIGS. 18 and 24, method 300 includes a block 316 where a cleaning process 272 similar as described above at block 116 is performed to the structure 400.

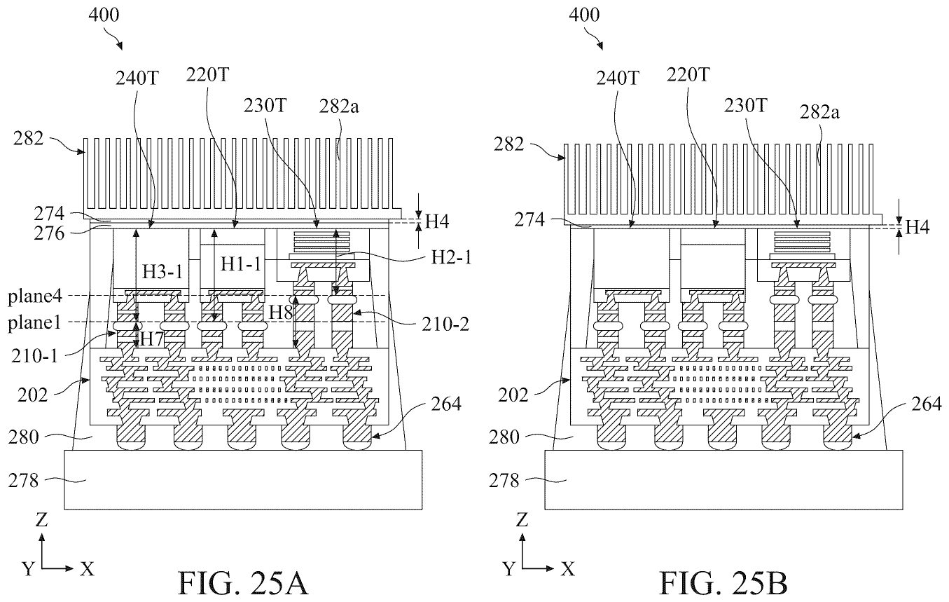

The structure 400 then undergoes operations at blocks 318 to 322 of method 300 in FIG. 18. The operations at blocks 318 to 322 are similar to those at blocks 118-122 of method 100 in FIG. 1. FIGS. 25A and 25B illustrate fragmentary cross-sectional views of the resulting structure 400, according to some aspects of the present disclosure. The structure 400 includes the package substrate 278 and the underfill 280 as described above. The structure 400 includes a TIM 274 and optionally a BSM structure 276 above the TIM 274 similar as described above with respect to FIGS. 11A-12B, except for the differences as follows. In the depicted embodiment, as the top surfaces (e.g., 220T, 230T, and 240T) of the device dies are coplanar, the TIM 274 may have a universal thickness of H4 as described above. By varying the heights of the micro bumps 210 therebelow, the top surfaces of the device dies (e.g., 220 and 240) directly contact the TIM 274 or the BSM structure 276, which have greater thermal conductivity than the molding compound 260. Thus, heat dissipation efficiency may be improved. With increase heat dissipation, the structure 400 may accommodate increased device density, scalability, and flexibility of designs. The structure 400 further includes the heat sink 282 attached to the TIM 274 similar as described above with respect to FIGS. 12A-12B. FIG. 25B is similar to FIG. 25A, except that the BSM structure 276 is omitted in FIG. 25B.

FIGS. 26A and 26B illustrate alternative structures 400′ fabricated by method 300. Differences from the embodiments represented in FIGS. 25A and 25B include the follows. Referring to FIG. 26A, the first micro bumps 210-1 have a height H7′ and the second micro bumps 210-2 have a height H8′ less than H7′ by about 10 μm to about 200 μm. In other words, the top surfaces of the first micro bumps 210-1 are in plane 1′, the top surfaces of the second micro bumps 210-2 are in plane 4′ lower than plane 1′, and a distance D4 between plane 1′ and plane 4′ about 10 μm to about 200 μm. The device dies 220, 230, and 240 have heights of H1′, H2′, and H3′, respectively. H1′ is the same as H3′, and smaller than H2′. FIG. 26B is similar to FIG. 26A, except that the BSM structure 276 is omitted in FIG. 26B.

FIG. 27 illustrate an alternative structure 400″ fabricated by method 300. Differences from the embodiments represented in FIG. 25A include that, the micro bumps 210 under the device die 220 have a height H9 greater than H7 and smaller than H8. In such embodiments, the micro bumps 210 under the device 220 are also referred to as third micro bumps 210-3, and the micro bumps 210 under the device die 240 are referred to as first micro bumps 210-1. The device dies 220, 230, and 240 may have heights H1-2, H2-1 and H3-1 as described above, respectively. In the depicted embodiment, H1-2 is smaller than H3-1 and greater than H2-1. Differences of fabrication of the structure 400″ from fabrication of the structure 400 as described above include the follows. In some embodiments, block 306 may include forming additional micro bumps over additional region(s) of the interposer 202. For example, to form the structure 400″ in FIG. 27, operations at block 304 includes forming the first micro bumps 210-1 in a first region 202-1′; operations at block 306 includes forming the second micro bumps 210-2 in the second region 202-2, and forming the third micro bumps 210-3 in the third region 202-3. Forming the third micro bumps 210-3 in the third region 202-3 may include forming a photoresist layer over the interposer 202 and the other micro bumps (e.g., the first micro bumps 210-1 and the second micro bumps 210-2), patterning (e.g., by photolithography, etching) the photoresist layer to form trenches, forming the third micro bumps 210-3 in the trenches, and removing the photoresist layer.

Method 100 and method 300 may be used separately or combined in fabricating a package structure including two or more device dies. For example, a method may combine blocks 302 to block 312 of method 300 and blocks 112 to 122 of method 100. For example, for a first device die and a second device die of a structure, the first micro bumps under the first device die and the second micro bumps under the second device die may have different heights, and portions of the TIM above the first device die and the second device die may have different thicknesses. For example, a structure may include three or more device dies having different heights, the micro bumps under the three or more device dies may have different heights, and/or portions of the TIM above the three or more device dies may have different thicknesses. FIGS. 28A-28B illustrate two examples of alternative structures. However, it is understood that the structures in this disclosure may have various combinations with various numbers, types, heights (e.g., including a height of the die portion and a height of the connecting structure), and arrangements (e.g., from a top view) of device dies, various heights of the micro bumps under the different device dies, and various thicknesses of the TIM above the device dies.

Referring to FIG. 28A, in an alternative structure 500, a difference from the structure 400′ in FIG. 26A includes that, the top surfaces 220T and 240T of the device dies 220 and 240 are in plane 6, the top surface 230T of the device die 230 is in plane 5 above plane 6. A distance D5 between plane 5 and plane 6 may be about 10 μm to about 500 μm. A thickness H10 of a portion of the TIM 274 above the device dies 220 and 240 is greater than the thickness H4 of the TIM 274 above the device die 230 as described above. H10 may be similar as H5 as described above and may be about 10 μm to about 500 μm.

Referring to FIG. 28B, in an alternative structure 600, a difference from the structure 500 in FIG. 26A includes that, the micro bumps 210 under the device 220 have a height H9′. H9′ may be less than H7′ and greater than H8′. In such embodiments, the micro bumps 210 under the device 220 are also referred to as third micro bumps 210-3, and the micro bumps 210 under the device die 240 are referred to as first micro bumps 210-1. The top surfaces of the third micro bumps 210-3 are in plane 7 between plane 1′ and plane 4′. The top surface 220T of the device die 220 is in plane 8 between plane 5 and plane 6. The portions of the TIM 274 over the device dies 220, 230, and 240 may have thickness H11, H4, and H10, respectively. H11 may be similar to H6 as described above in FIG. 17.

The BSM structure 276 in FIGS. 27-28B may be omitted, so that the TIM 274 is directly disposed on the top surfaces of the device dies 220, 230, and 240, similar to FIGS. 12B and 16B.

Although not intended to be limiting, one or more embodiments of the present disclosure provide many benefits to a semiconductor package structure. For example, the package structure integrates device dies with different heights, and by performing local thinning process(s) and/or by forming micro bumps with different heights under the device dies, top surfaces of the device dies are in contact with heat dissipation layers (e.g., the BSM structure or the TIM). Thus, heat dissipation of the device dies may be improved, and overall performance of the semiconductor package may be improved. The package structure integrates device dies with various functionalities in a single package and may provide increased device density, scalability, and flexibility of designs.

In one exemplary aspect, the present disclosure is directed to a method. The method includes providing an interposer structure including conductive paths, forming micro bumps over the interposer structure and connected to the conductive paths, bonding a first die and a second die onto the micro bumps, forming a molding compound over and around the first die and the second die, performing a planarization process to expose a top surface of the second die, forming a trench in the molding compound to expose a top surface of the first die, forming a thermal interface material (TIM) layer in the trench and over the top surface of the second die, bonding the interposer structure to a substrate, and attaching a heat sink onto the TIM layer. The first die has a first height and the second die has a second height greater than the first height.

In some embodiments, the first die is a system-on-chip (SoC) die or a system-on-integrated-chips (SoIC) die, and the second die is a high bandwidth memory (HBM) die. In some embodiments, the method further includes bonding a third die onto the micro bumps. The third die has a third height smaller than the first height, and the method further includes extending the trench to expose a top surface of the third die. In some embodiments, the method further includes performing a cleaning process before forming the TIM layer in the trench and over the top surface of the second die. In some embodiments, before forming the TIM layer in the trench and over the top surface of the second die, the method further includes forming a backside metal (BSM) layer in a bottom and a sidewall of the trench and on the top surface of the second die. The TIM layer is formed over the BSM layer. In some embodiments, the micro bumps have a same height. In some embodiments, the micro bumps include first micro bumps and second micro bumps having different heights. In some embodiments, the first die is a high bandwidth memory (HBM) die, and the second die is a system-on-chip (SoC) die or a system-on-integrated-chips (SoIC) die. In some embodiments, the first die and the second each include a die and a connecting structure, the connecting structure includes conductive traces, a passivation layer surrounding the conductive traces, and upper micro bumps connected to the micro bumps.

In another exemplary aspect, the present disclosure is directed to a method. The method includes providing an interposer structure including a first region and a second region, forming first micro bumps over the first region and second micro bumps over the second region, bonding a first die onto the first micro bumps and a second die onto the second micro bumps, depositing a molding compound around the first die and the second die, bonding the interposer structure to a substrate, and bonding a heat sink to the first die and the second die. The first micro bumps have a first height and the second micro bumps have a second height greater than the first height.

In some embodiments, the first die has a third height and the second die has a fourth height smaller than the third height. In some embodiments, the heat sink is bonded to the first die and the second die by a thermal interface material (TIM). In some embodiments, the interposer structure further includes a third region, the method further includes forming third micro bumps over the third region, the third micro bumps have a third height greater than the second height, the method further includes bonding a third die onto the third micro bumps, the molding compound is further deposited around the third die, and the heat sink is further bonded to the third die. In some embodiments, forming the first micro bumps over the first region and the second micro bumps over the second region includes forming a first photoresist layer over the interposer structure, patterning the first photoresist layer to form first trenches in the first photoresist layer over the first region, forming the first micro bumps in the first trenches, removing the first photoresist layer, forming a second photoresist layer over the interposer structure and the first micro bumps, patterning the second photoresist layer to form second trenches in the second photoresist layer over the second region, forming the second micro bumps in the second trenches, and removing the second photoresist layer. In some embodiments, top surfaces of the first die and the second die are coplanar. In some embodiments, depositing the molding compound further deposits the molding compound over a top surface of the first die and a top surface of the second die, the top surface of the first die is higher than the top surface of the second die, and after depositing the molding compound, the method further includes performing a planarization process to expose the top surface of the first die, and performing a grinding process to form a trench to expose the top surface of the second die. In some embodiments, the method further includes forming a thermal interface material (TIM) in the trench and on the top surface of the first die. A thickness of the TIM over the first die is less than a thickness of the TIM over the second die, and the heat sink is bonded to the first die and the second die by the TIM.

In yet another exemplary aspect, the present disclosure is directed to a package structure. The package structure includes a substrate, an interposer bonded to the substrate, a first die and a second die bonded to the interposer, a thermal interface material (TIM) layer disposed over the first die and the second die, and a heat sink bonded to the TIM layer. A thickness of a first portion of the TIM over the first die is greater than a thickness of a second portion of the TIM over the second die.

In some embodiments, the first die is bonded to the interposer by first micro bumps and the second die is bonded to the interposer by second micro bumps, the first micro bumps and the second micro bumps have different heights. In some embodiments, the first die is a system-on-chip (SoC) die or a system-on-integrated-chip (SoIC) die, and the second die is a high bandwidth memory (HBM) die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing an interposer structure including conductive paths;
forming micro bumps over the interposer structure and connected to the conductive paths;
bonding a first die and a second die onto the micro bumps, wherein the first die has a first height and the second die has a second height greater than the first height;
forming a molding compound over and around the first die and the second die;
performing a planarization process to expose a top surface of the second die;
forming a trench in the molding compound to expose a top surface of the first die;
forming a thermal interface material (TIM) layer in the trench and over the top surface of the second die;
bonding the interposer structure to a substrate; and
attaching a heat sink onto the TIM layer.

2. The method of claim 1, wherein the first die is a system-on-chip (SoC) die or a system-on-integrated-chips (SoIC) die, and the second die is a high bandwidth memory (HBM) die.

3. The method of claim 1, further comprising bonding a third die onto the micro bumps,
wherein the third die has a third height smaller than the first height, and
wherein the method further comprises extending the trench to expose a top surface of the third die.

4. The method of claim 1, further comprising performing a cleaning process before forming the TIM layer in the trench and over the top surface of the second die.

5. The method of claim 1, before forming the TIM layer in the trench and over the top surface of the second die, further comprising forming a backside metal (BSM) layer in a bottom and a sidewall of the trench and on the top surface of the second die,
wherein the TIM layer is formed over the BSM layer.

6. The method of claim 1, wherein the micro bumps have a same height.

7. The method of claim 1, wherein the micro bumps include first micro bumps and second micro bumps having different heights.

8. The method of claim 1, wherein the first die is a high bandwidth memory (HBM) die, and the second die is a system-on-chip (SoC) die or a system-on-integrated-chips (SoIC) die.

9. The method of claim 1, wherein the first die and the second each include a die and a connecting structure,
wherein the connecting structure includes conductive traces, a passivation layer surrounding the conductive traces, and upper micro bumps connected to the micro bumps.

10. A method, comprising:
providing an interposer structure including a first region and a second region;
forming first micro bumps over the first region and second micro bumps over the second region, wherein the first micro bumps have a first height and the second micro bumps have a second height greater than the first height;
bonding a first die onto the first micro bumps and a second die onto the second micro bumps;
depositing a molding compound around the first die and the second die;
bonding the interposer structure to a substrate; and
bonding a heat sink to the first die and the second die.

11. The method of claim 10, wherein the first die has a third height and the second die has a fourth height smaller than the third height.

12. The method of claim 10, wherein the heat sink is bonded to the first die and the second die by a thermal interface material (TIM).

13. The method of claim 10, wherein the interposer structure further includes a third region,
wherein the method further comprises forming third micro bumps over the third region,
wherein the third micro bumps have a third height greater than the second height,
wherein the method further comprises bonding a third die onto the third micro bumps,
wherein the molding compound is further deposited around the third die, and
wherein the heat sink is further bonded to the third die.

14. The method of claim 10, wherein forming the first micro bumps over the first region and the second micro bumps over the second region includes:
forming a first photoresist layer over the interposer structure;
patterning the first photoresist layer to form first trenches in the first photoresist layer over the first region;
forming the first micro bumps in the first trenches;
removing the first photoresist layer;
forming a second photoresist layer over the interposer structure and the first micro bumps;
patterning the second photoresist layer to form second trenches in the second photoresist layer over the second region;
forming the second micro bumps in the second trenches; and
removing the second photoresist layer.

15. The method of claim 10, wherein top surfaces of the first die and the second die are coplanar.

16. The method of claim 10, wherein depositing the molding compound further deposits the molding compound over a top surface of the first die and a top surface of the second die;
wherein the top surface of the first die is higher than the top surface of the second die; and
after depositing the molding compound, the method further comprises:
performing a planarization process to expose the top surface of the first die, and
performing a grinding process to form a trench to expose the top surface of the second die.

17. The method of claim 16, further comprising forming a thermal interface material (TIM) in the trench and on the top surface of the first die,
wherein a thickness of the TIM over the first die is less than a thickness of the TIM over the second die, and
wherein the heat sink is bonded to the first die and the second die by the TIM.

18. A package structure, comprising:
a substrate;
an interposer bonded to the substrate;
a first die and a second die bonded to the interposer;
a thermal interface material (TIM) layer disposed over the first die and the second die; and
a heat sink bonded to the TIM layer,
wherein a thickness of a first portion of the TIM over the first die is greater than a thickness of a second portion of the TIM over the second die.

19. The package structure of claim 18, wherein the first die is bonded to the interposer by first micro bumps and the second die is bonded to the interposer by second micro bumps,
wherein the first micro bumps and the second micro bumps have different heights.

20. The package structure of claim 18, wherein the first die is a system-on-chip (SoC) die or a system-on-integrated-chip (SoIC) die, and the second die is a high bandwidth memory (HBM) die.
